(19) United States
(12) Patent Application Publication
(10) Pub. No.: US 2011/0197953 A1
(43) Pub. Date: Aug. 18, 2011

(54) METHOD FOR CONNECTING THIN-FILM SOLAR CELLS AND THIN-FILM SOLAR MODULE

(75) Inventor: Alexander Pfeuffer, Bielefeld (DE)

(73) Assignee: Malibu GMBH & Co. KG, Bielfeld (DE)

(21) Appl. No.: 13/124,058

(22) PCT Filed: Sep. 15, 2009
(86) PCT No.: PCT/EP2009/061932

§ 371 Date: Apr. 13, 2011

(30) Foreign Application Priority Data
Oct. 13, 2008 (DE) 10 2008 051 469.1

(51) Int. Cl. H01L 31/05; H01L 31/0224

(52) U.S. Cl. 136/249; 438/66; 257/E31.124

(57) ABSTRACT

A method for forming at least one electrically conducting contact area on a thin-film solar module. The method steps include providing a plurality of thin-film solar cells including cell material layers; applying the thin-film solar cells to a support material; and forming the at least one electrically conducting contact area on the thin-film solar module by using a cold gas spraying process. A thin-film solar module includes a support material, a plurality of cell material layers applied to the support material, and at least one electrically conducting contact area formed on the thin-film solar module by a cold gas spraying process.

This application is a national stage of International Application PCT/EP2009/061932, filed Sep. 15, 2009, and claims benefit of and priority to German Patent Application No. 10 2008 051 469.1, filed Oct. 13, 2008, the content of which Applications are incorporated by reference herein.

### BACKGROUND AND SUMMARY

The present disclosure relates to a method for forming at least one electrically conducting contact area on a thin-film solar module. The method steps include providing a plurality of thin-film solar cells including cell material layers and applying the thin-film solar cells to a support material. The present disclosure also relates to a solar module formed by the above-noted method.

A thin-film solar module, as noted above, comprises a plurality of solar cells arranged on a support material, such as a substrate or superstrate, which may be a glass panel. Each generate current according to the principle of a photodiode, where electron-hole pairs are generated by incident light, these being separated by suitable semiconductor layers. This separation can be caused by an electric field which can be produced by doping the semiconductor layers.

In order to be able to use solar cells as part of a power circuit, a reliable contacting of the semiconductor layers is required in order to lead off the photocurrent from the semiconductor layers.

In the case of thin-film solar cells, the series connection of the individual cells is accomplished by a suitable process sequence of cutting steps and a subsequent structuring, for example, by laser ablation or with the aid of a mechanical scoring of the deposited layers. The monolithic connection hereby produced is shown on the finished module, for example, by a characteristic needle strip pattern.

Furthermore, conductor paths or metal strips, hereinafter called current collecting paths, for leading away the photocurrent are formed at the outermost two individual cells, which conductor paths, may, in turn, be connected via further current-conducting paths, hereinafter called current paths, for example, to a junction box for the connection of external conductors.

The current collecting paths and the optionally provided current paths usually consist of tin-plated copper strips. It is known to adhesively bond these strips to the semiconductor layers by an electrically conductive adhesive. The known adhesives used for this purpose, for example, have a plurality of disadvantages such as an unsatisfactory resistance of the adhesive to moisture and higher temperatures. The contamination of individual cells by components of the adhesive should be assessed equally critically. In addition, the relatively complex mechanical and thermal process control during application of the adhesive increases the assembly expenditure.

Alternatively, the current collecting paths and/or the current paths can be connected to the solar cells in an electrically conducting manner by a thermal soldering process. A problem here is that not all materials can be soldered conventionally, for example, ceramic, TCO, or transparent conductive oxide such as, for example, ZnO, SnO₂, ITO or aluminium. Since in addition not all metals, such as, for example, aluminium, are solderable, it is necessary to extensively apply further intermediate layers of nickel/vanadium when implementing the back contact. Furthermore, local mechanical stresses caused by spot soldering are disadvantageous.

It is also known to apply the current collecting paths and the current paths by ultrasound soldering which can also be used in cases in which a conventional soldering process fails. A disadvantage here, however, is that a very expensive special solder is required for the ultrasound soldering of metal strips to TCO. The relatively complex mechanical process control and the difficult process monitoring also have a negative effect.

It should be noted that DE 30 011 24 OS discloses a method for applying electrically conducting contacts to the surface of a conventional solar cell, not configured as a thin-film solar cell. Particles of a metallic material are formed by thermal spraying from a temperature above the alloying temperature of this material and silicon and in which the particles are sprayed towards the surface from such a distance that they reach the surface at a temperature at which they alloy with the silicon and thereby adhere to the silicon surface. A comparable process is known from U.S. Pat. No. 6,620,645 B2. As a result of the high temperatures, for example, see column 4, lines 6 and 7 of the '645 document, the methods are not suitable for applying conductor paths to thin-film solar cells because, for example, the severely heated particles oxdize upon contact with oxygen. In the case of a glass support, the thermal loading can also lead to its fracture.

Against this background, the present disclosure provides for an optimized method for applying electrically conducting contacts to thin-film solar modules having one or more thin-film solar cells.

The present disclosure thus relates to a method for forming at least one electrically conducting contact area on a thin-film solar module. The method steps include providing a plurality of thin-film solar cells including cell material layers; applying the thin-film solar cells to a support material; and forming the at least one electrically conducting contact area on the thin-film solar module by using a cold gas spraying process. A thin-film solar module includes a support material; a plurality of cell material layers applied to the support material; and at least one electrically conducting contact area formed on the thin-film solar module by a cold gas spraying process.

The method includes forming at least one electrically conducting contact area on a thin-film solar module that includes at least one or a plurality of solar cells that include a plurality of cell material layers applied to a support material such as a substrate or a superstrate, in which the at least one electrically conducting contact area is formed or fixed on the solar module by a cold gas spraying process. The cold gas sprayed contacts adhere particularly well on glass if they consist of aluminium.

Embodiments according to the present disclosure are further discussed below.

It is within the scope of the present disclosure to form the contacts, for example, current collecting paths and/or current paths, by cold gas spraying.

Alternatively, it is also within the scope of the present disclosure to use cold gas spraying in order, for example, to apply metal contacts such as, for example, copper contacts, in particular copper conductor paths, to the support material, such as a substrate or a superstrate, or fix to this.

Cold gas spraying differs from thermal spraying processes such as, for example, a flame spraying, electric arc spraying or plasma spraying processes, in that the sprayed-on fine metal particles are not processed in a molten state. As a result, cold gas spraying has an advantage that the metal properties are maintained largely unchanged and that the workpiece to be sprayed is not influenced or even destroyed by high temperatures. Oxidation of the metal particles is prevented by the comparatively moderate temperatures. The current conductor paths and the current paths are preferably applied directly to the support material, for example, without an intermediate layer.

In the cold gas spraying process, metal particles are certainly heated but not melted. This is unlike thermal spraying processes, as noted above. The metal particles are sprayed through a nozzle, for example, a Laval nozzle, at ultrasonic velocity. The carrier gas heated to several hundred degrees expands in the nozzle and brings about the necessary high velocities of the particles. The metal particles are deposited in a morphologically dense low-oxide layer on the support material substrate, for example, a substrate or superstrate.

Fine aluminium particles, for example, 35 μm may be sprayed by cold gas spraying according to the present disclosure, which particles have a maximum temperature of 300° C., or, for example, 150° C., when impinging upon the substrate or superstrate.

Metal current collecting paths or current paths are applied to solar cells by cold gas spraying using special contacting patterns. The contacting of the solar cells and the application of the current paths may be accomplished with only one component, for example, a metal powder. This can, however, also be formed as a combination of different metals or metal alloys.

A feature of the method, according to the present disclosure, is the high process-engineering flexibility in the contacting of the cells if the spray nozzle is moved by a robot system.

By this method, very complex contacting patterns can be produced on the solar module. It is also possible to adapt rapidly to different substrate sizes without protracted set-up times being required or the production line even needing to be interrupted.

In the above process, mechanical and electrical properties similar to those of the starting material can be achieved in the sprayed-on layer.

Usually 20-90% of the electrical conductivity is achieved depending on the metal and the process parameters.

An additional increase of the electrical conductivity can be achieved by a subsequent thermal process step. In such a case, the temperature may be more than 50%, or, for example, ⅔ of the melting point of the sprayed-on metal. In such a case, the heating can advantageously take place locally restricted to the metal path by, for example, laser, flame or induction.

The electrical resistance does not vary within the measurement accuracy if the sample is exposed to an atmosphere having elevated air humidity and temperature, for example, 85%, 85° C., 1000 hours.

The cold gas spraying process includes a high deposition rate and a high attainable degree of automation. At the same time, the support material experiences only very low thermal and mechanical loading. The metals, for example, aluminium or tin, can be sprayed or deposited directly onto glass or ceramic.

For improved adhesion on glass and ceramic, mixtures of different pure metals, or alloys, and/or having different grain sizes, or powder sizes, can be sprayed. Multilayer tracks of different pure metals/alloys can also be easily achieved.

By a suitable spray nozzle, jet widths of several millimetres width, for example, <4 mm, can be achieved. As a result, it is possible to work without a mask during application which further minimises the spraying losses despite the existing high degree of adhesion.

The process, according to the present disclosure, additionally has an advantage that the applied conductor path usually does not form an exact rectangle in cross-section. The cross-sectional area of the sprayed-on conductor paths rather corresponds to a Gaussian distribution, see FIG. 8. This has an advantage that, during the subsequent production of a glass-glass composite, included air can be pressed out significantly more easily than in the case of rectangular conductor paths of metal strips. As a result, thinner PVB films can be used for a successful composite. The height of the sprayed-on conductor paths can also be varied very easily through the choice of process parameters.

The process, according to the present disclosure, can be applied advantageously to form current collecting paths on thin-film solar modules which are configured as so-called glass-glass modules comprising two glass panels.

According to an advantageous embodiment of the present disclosure, the metal paths are made of relatively coarse powder, for example, grain sizes >35 μm, which optimizes the process particularly from the safety technology point of view since the risk of dust explosions during production in such a manner is negligible.

In the case of coarser powders, subsequent cleaning of the support material can possibly even be omitted.

Another advantage of the cold gas spraying process, according to the present disclosure, is that in different combinations conductor paths according to the prior art can be combined with conductor paths produced by cold gas spraying.

Thus, according to an advantageous embodiment of the present disclosure, cold gas spraying is used to apply copper strips which serve as the actual current collector paths.

The electrical contacting of the copper strips with the solar cells is, however, no longer accomplished with conducting adhesives but by sprayed-on metal in the cold gas spraying process.

In such a case, the metal is applied, for example, in spots or in the form of a continuous line. This has several advantages. Thus, copper strips have a higher current-carrying capacity than aluminium paths having the same cross-section. If, in addition, a continuous metal path is sprayed on, the tinning of the copper strip can optionally be omitted since a corrosion protection is already achieved by the sprayed-on metal layer. In addition, a contacting directly onto sputtered aluminium back contacts/reflectors is thereby possible. A nickel-vanadium terminating layer is not necessary.

According to another embodiment of the method of the present disclosure, it is also possible to apply the current collecting paths by the cold gas spraying process whilst the current paths are produced from conventional metal strips or conversely.

According to relevant standardization, for example, DIN EN 61646, insulation testing/creep current testing under wet conditions for the testing of thin-film solar cells, the outer edges, such as the outer 1-2 cm on the substrate or superstrate coated with cell layers, must be freed from these layers so that there is a sufficient mechanical and electrical safety distance to the module edge. In addition, TCO corrosion which frequently starts from the module edge and progresses into the module interior is arrested. The glass substrate or superstrate is therefore exposed at the edge so that this area can be used for current transport. The current collecting paths are sprayed directly onto the active cell layers or in an overlapping manner to the glass substrate or superstrate.

Experiments show that when using aluminium for cold gas spraying, the contacting of the active cell layers is particularly good if the sprayed-on aluminium both contacts these cell layers in one region and the substrate or superstrate, in particular made of glass, in another region since this adheres particularly well to glass or forms a chemical compound with glass. Also in favor of aluminium is the fact that it is inexpensive and has an extremely good density-conductivity ratio.

In a module whose structures corresponds to the prior art, an insulation film is required which locally electrically separates the current paths from the active layers of the cells. At the points of intersection with the current collecting paths, a nickel layer can then optionally be additionally sprayed thereon locally.

In another embodiment, according to the present disclosure, both the current collecting paths and also the current paths are formed in the de-coated edge region of the solar module.

The current collecting paths are applied, for example, sprayed, as in the first embodiment noted above, while the current paths are guided only over the edge-deleted zone without touching the active layers of the solar cell. An advantage here is that an insulating film for the current paths can be dispensed with and the connections can sit at the module edge, which is advantageous for so-called semi-transparent, for example, partially light-transmitting, modules.

Short metal strips or wires can form the loose ends of the current collecting paths or current paths when these are fixed in direct connection by cold-gas-sprayed metal on the substrate. The loose ends or wires can be guided through holes or slits in the back glass or over the module edge.

Furthermore, the electrical contacting of the conductor paths can be accomplished by cold gas-sprayed metal directly through a hole in the support material or the back glass. When using aluminium, the drill-hole can be closed in a weather-resistant manner by the ensuing chemical bond with the glass. With this contacting scheme, an insulation film can be dispensed with, which lowers the manufacturing costs and simplifies the manufacturing process.

According to another embodiment of the present disclosure, the current paths without insulating film are not formed at the edge of the support material but further towards the center of the module. In this case it is necessary that the individual solar cells or the entire module separate the region of the active cells from that of the current path by way of an insulation structure which extends as far as onto the glass substrate or superstrate, for example, by laser ablation or mechanical scoring, in order to avoid a short circuit. In order to improve the metal adhesion on the substrate or superstrate, the fields for the current paths can be provided with additional insulation structures, such as scoring the deposited layer. In addition, further insulation structures can be attached for better adhesion of the current collecting paths.

Whereas in the preceding embodiments both the current collecting paths and also the current paths have been attached on the front glass with active cell layers, this is solved differently in another embodiment of the present disclosure for glass-glass modules. In this embodiment, one of the current collecting paths may be sprayed onto the front glass in an overlapping manner to the edge-deleted zone. The current paths, on the other hand, are sprayed onto the back glass before assembly of the module. A film, for example, a PVB film which adhesively bonds the front and the rear glass, has two stamped-out holes or slits which lie at the subsequent point of intersection of current collector path and current path. Electrical contact between the paths could be accomplished by conductive adhesives or low-melting alloys for metals.

The curing process of the conductive adhesive or the melting of the alloys or metals can take place, for example, during the lamination process.

In this manner of contacting, no active cell surface is lost through insulation structures. The PVB film additionally functions as insulation film. Here it is advantageous that no additional insulation film need be used and that the position of the junction box is arbitrary.

According to another embodiment of the present disclosure, the contacting of the current collector paths is guided through holes to the side facing away from the cell layers. On this side, the current paths can now be guided to the junction box.

In the superstrate construction, the sunlight passes first through the transparent support material, for example, glass, and then the functional layers which are deposited on the support.

In the substrate approach, optical transparency of the support material can be dispensed with since the support is located in the beam path after the functional layers.

Instead of only one junction box, it is within the scope of the present disclosure to use two such boxes. Then, no current paths are required.

### BRIEF DESCRIPTION OF THE DRAWINGS

FIG. 1 shows a plan view of a known thin-film solar module.

FIGS. 2A and 2B show a known thin-film solar cell in cutaway and enlarged view in an edge region.

FIG. 3A shows a schematic sectional view of a thin-film solar module provided with cold-gas sprayed current collecting paths, according to the present disclosure.

FIG. 3B shows a sectional view of a thin-film solar module in a known state of process before a cold gas spraying step shown in FIG. 3C according to the present disclosure.

FIG. 3C shows a sectional view of an edge region of a thin-film solar module provided with a cold-gas sprayed current collecting path, according to the present disclosure.

FIGS. 4 and 5 show plan views of embodiments of thin-film solar modules, according to the present disclosure.

FIG. 6A shows an exploded view of an embodiments of a thin-film solar module, according to the present disclosure.

FIG. 6B shows a sectional view through a section of the thin-film solar module of FIG. 6A.

FIGS. 7A and B show sectional views of embodiments of thin-film solar modules, according to the present disclosure.

FIG. 8 shows a measurement diagram of a cold gas sprayed current collecting path, according to the present disclosure.

### DETAILED DESCRIPTION

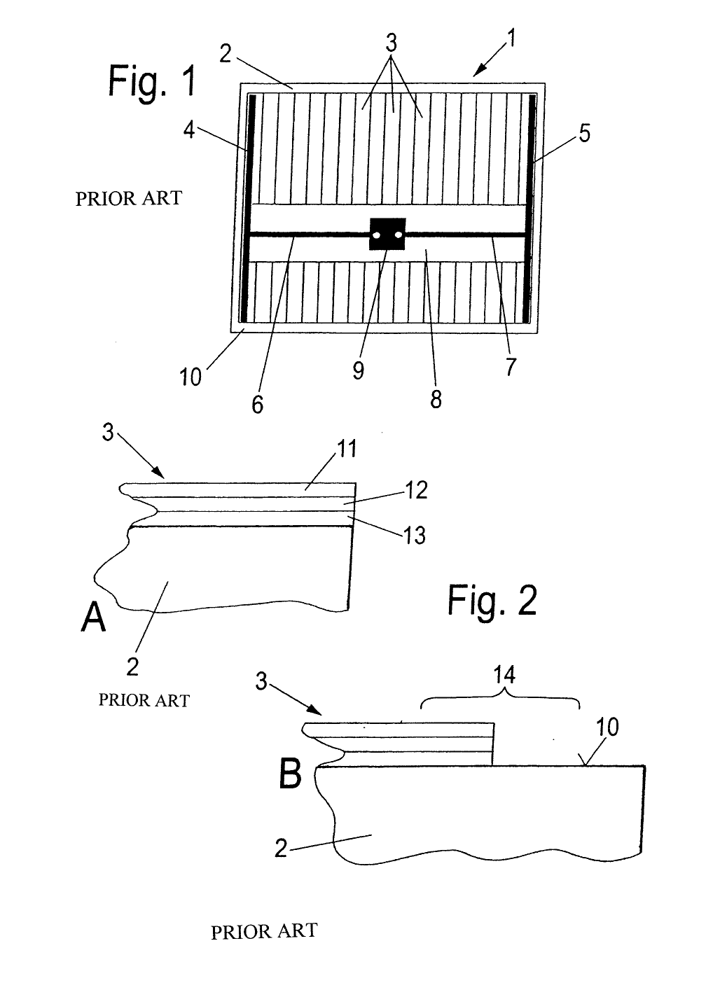

FIG. 1 shows a known thin-film solar module 1 which is constructed as a base on a support or support material 2 which can be formed as a superstrate, for example, as a glass panel. Configurations having an optically transparent or non-transparent substrate as support material are also possible, according to the present disclosure.

The thin-film solar module 1 comprises a plurality of solar cells 3 which are formed in a monolithic connection on the support 2, which is indicated in FIG. 2 by separating dashes between the solar cells 3. Due to the monolithic connection, it is possible to lead off the current of one solar cell to another.

Located at a first and last thin-film solar cell 3 of the solar cells connected in series with one another are current collecting paths 4, 5 which in turn contact current paths 6 and 7, which are guided to a junction box 9 for the connection of external electrical conductors. It is within the scope of the present disclosure to eliminate the current paths if one junction box is positioned directly on the current collecting paths.

The equal-length current paths 6 and 7 usually run approximately centrally to the entire thin-film solar module 1 direction via the individual thin-film solar cells 3.

In order that no short circuit occurs, it is necessary to arrange or form an insulating layer, achieved, for example by an insulating film 8, between the thin-layer solar cells 3 and the current paths 6 and 7.

The current-generating thin-film solar cells 3 occupy in total a somewhat smaller area that the support material or the support 2 so that a free edge zone 10 is afforded peripherally on the support 2 which serves to achieve a perfect insulation.

The free edge zone 10 is formed after applying the various solar-cell material layers by removing a corresponding edge region of these material layers and is thus also designated as a devarnished edge zone.

FIG. 2A shows a side view of an edge section of the support 2 after application of various layers 11, 12, 13 and before removal of these layers to form the free edge zone 10. The cell layers to be removed here comprise a back contact layer, or electrically conductive layer A, designated by number 11, an absorber layer 12, for example, made of silicon, or amorphous or microcrystalline, and a so-called TCO layer, or transparent conducting oxide, or electrically conductive layer B, designated by number 13, which adjoins the support material 2.

The same applies for superstrates in which solar irradiation comes from the other side, that is from the side which receives the cell layers. The layers are arranged and designated accordingly.

After removal of an edge region of these layers, the edge-deleted zone 10 is formed in the manner shown in FIG. 2B, in which the support material 2 is exposed, which is required for the safe function of the entire thin-layer module.

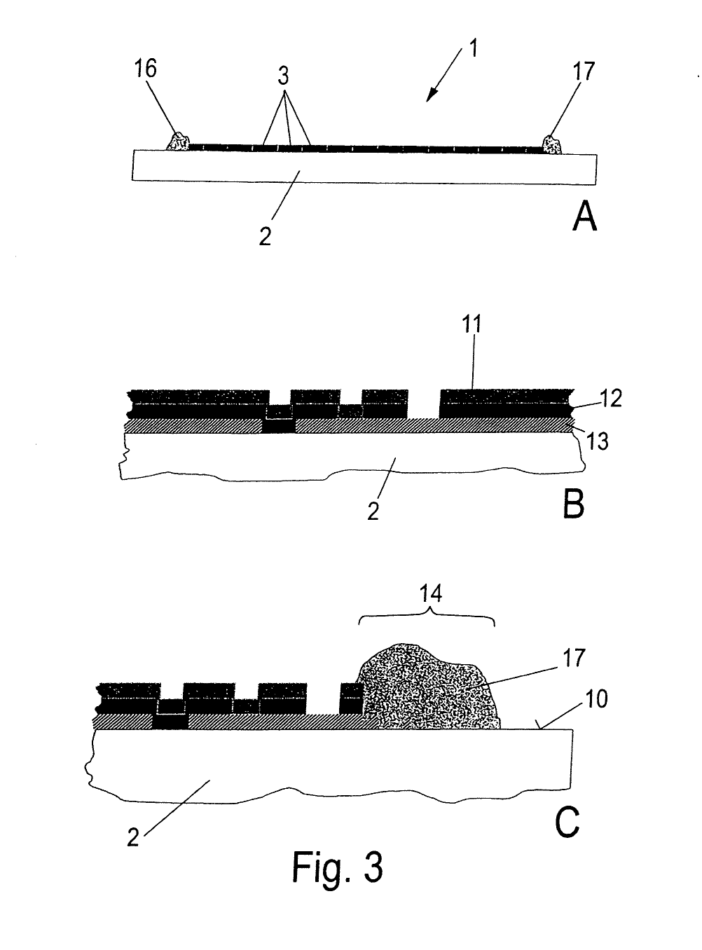

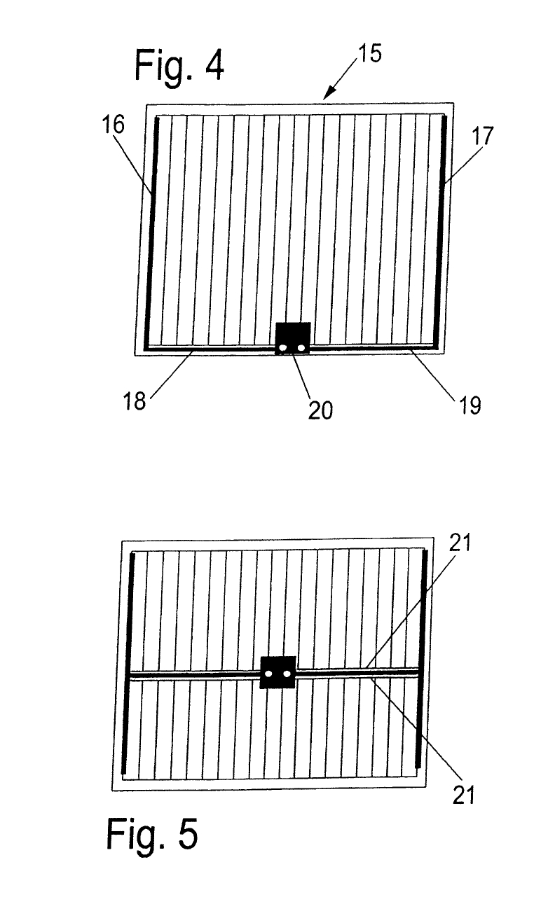

FIG. 3A shows a sectional view of a thin-film solar module 1 which is divided into individual thin-film solar cells 3 which are interconnected by a monolithic connection.

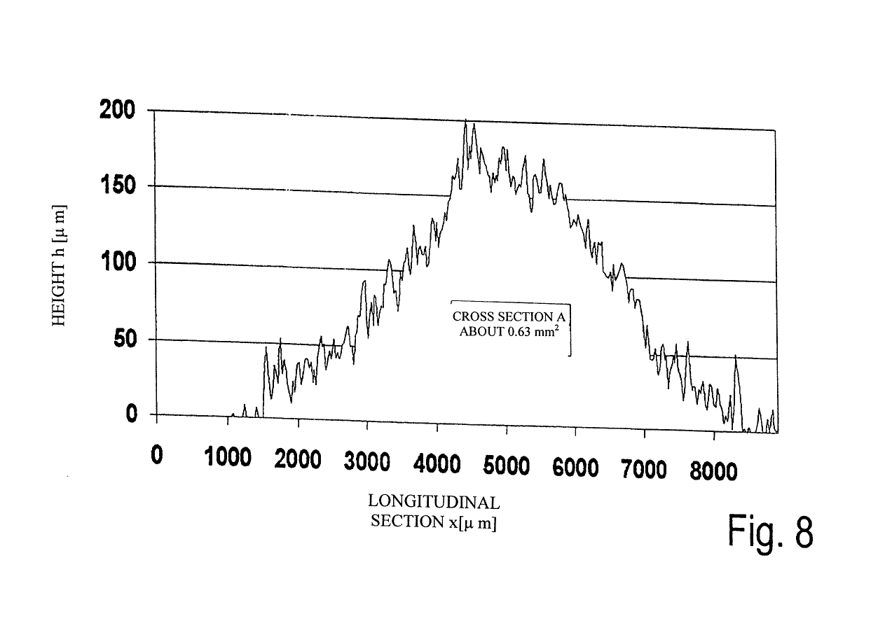

According to the present disclosure, at least one electrically conducting contact, for example, at least one or more of the current collecting paths 16, 17 and/or the current paths (not shown) of the solar module 1 is formed or fixed on the solar module 1 by spraying a metal in the cold gas spraying process. The current collecting paths 16 and 17 are shown substantially larger than in practice. The real dimensions of an exemplary current collecting path 16, 17 are represented by the measurement diagram in FIG. 8.

FIG. 3B shows a thin-film solar module according to the prior art with a monolithic connection before a process of cold gas spraying shown in FIG. 3C according to the present disclosure.

FIG. 3C shows the edge region of a thin-film solar module 1 having a free edge zone 10 and having a current collecting path 17 which contacts this zone 10 in certain sections and the active cell layers 11, 12, 13 in certain sections.

Aluminium powder forms a good adhering compound with the glass, shown in FIG. 3C, for example, as a glass support 2. The application of the current collecting path 17 to the thin-film cell 3 causes a partial destruction of the cell 3 as during soldering processes. In this case, the sprayed-on aluminium powder penetrates completely or partially through the cell layers. The essential thing here, however, is that perfect contacting with the current-conducting layers and a reliable adhesion on the substrate come about.

FIG. 4 shows a thin-film solar module 15, according to the present disclosure, in which the current collecting paths 16, 17 and the current paths 18, 19 have been applied by a cold gas spraying. These can also be formed at other positions of the solar module 15 by using the process in accordance with the present disclosure.

The current-collecting paths 16 and 17 may lie partially on the free edge zone 10 and partially on the outer material layers or cell layers of the solar cells.

According to an embodiment of the present disclosure shown in FIG. 4, current paths 18 and 19 also run on the free edge zone 10. The current paths 18, 19 are, however, not in contact with the individual solar cells with the result that no additional insulation is required, as is the case in the prior art, as shown in FIG. 1. In accordance with that shown and described in FIG. 4, the assembly effort can be reduced and the manufacturing costs lowered. In addition, it is also possible, within the scope of the present disclosure, to form connections for external conductors, such as junction box 20, in the edge region of the solar module in a simple manner, which is advantageous in the case of semi-transparent modules, since less shading by the junction box occurs as a result.

FIG. 5 shows another embodiment, according to the present disclosure, of a thin-film solar module where an additional insulation film between the solar cells and the current paths is also dispensed with as according to the embodiment of FIG. 4. This is possible since the individual solar cells acquire a so-called insulation structure 21 in order to maintain functional reliability. In this case, the cell is separated, for example, by lasing so that no short circuit can occur. However, the effective cell area is somewhat smaller as a result. According to an embodiment of the present disclosure, it is then possible to spray on the current paths in the cold gas spraying process, whereby a secure fixing on the glass substrate is achieved since the sprayed-on aluminium powder or the sprayed-on current path comes into direct contact with the glass substrate and holds securely thereon. The functional layers are penetrated in this delimited region and are, for the most part, destroyed. Additional insulation structures in the region of the current paths may promote the adhesion on the substrate.

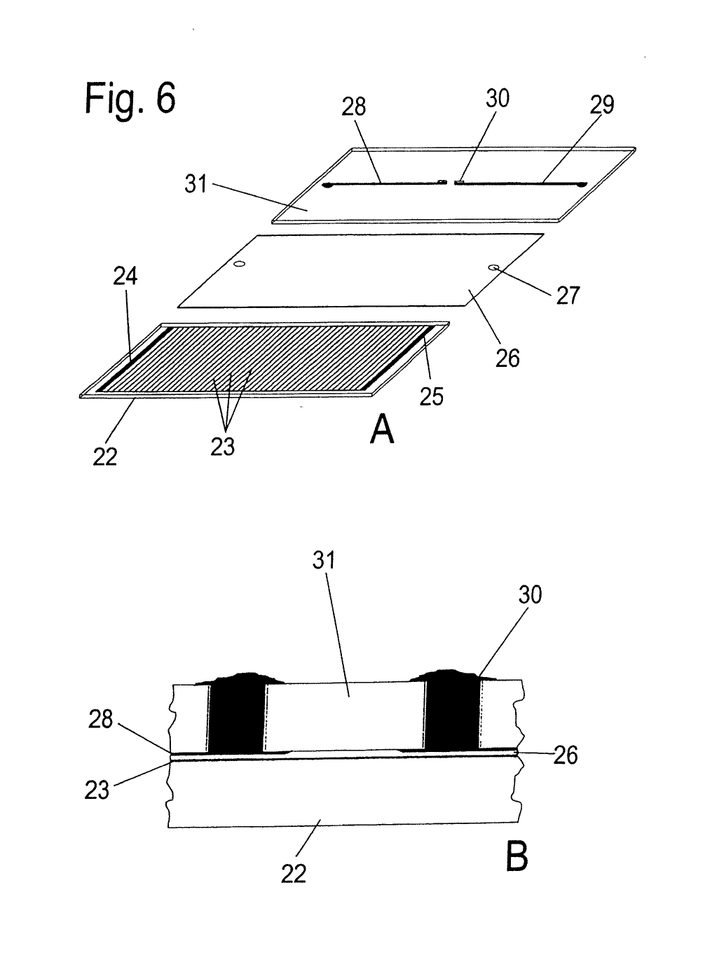

FIG. 6A shows an embodiment, according to the present disclosure, of a thin-film solar module, as a glass-glass design, for example, a front glass 22 and a back glass 31, in an isometric exploded view. Front glass 22 includes thin-film solar cells 23 which are provided with current collecting paths 24 and 25, according to the present disclosure, at the first and last cell, as has already been described.

According to the prior art, one or more film(s) 26, for example, a PVB film and optionally an additional insulating film 26, are provided between the glass panels for insulating and for connecting the panels. For current guidance, according to the present disclosure, this film 26 has holes or slits in the region of intersection or the contacting region of the current collecting paths 24 and 25 and the current paths 28 and 29. These current paths 28 and 29 are sprayed on underneath the back glass 31 and run from the points of intersection or contact points as far as holes 30 in the middle of the back glass 31, which are used for connection to a junction box.

As shown in an embodiment of the present disclosure in FIG. 6B, the holes 30 in the back glass 31 can also advantageously be filled by the cold gas spraying process. By this, a very simple contacting on the back of the entire glass-glass module is possible. The holes are also “densely” filled.

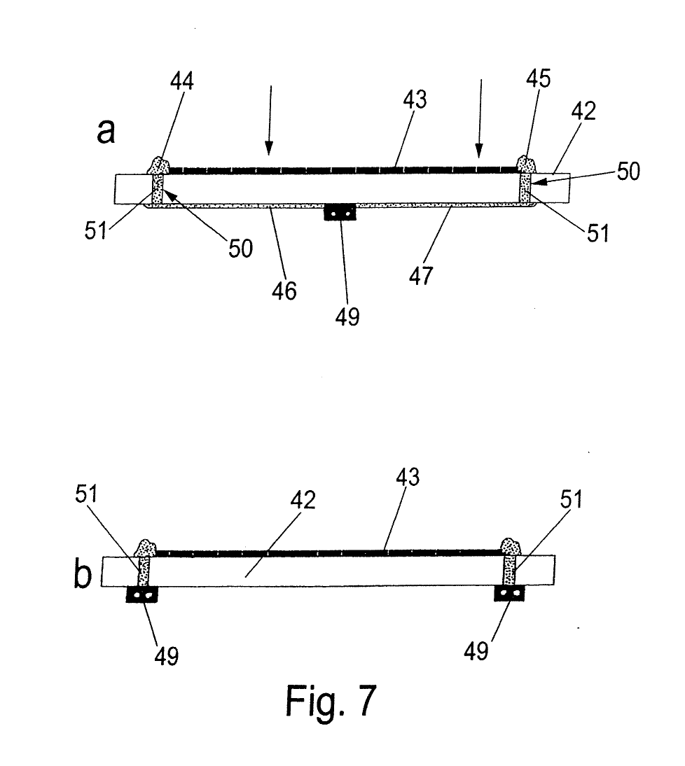

FIG. 7A shows an embodiment, according to the present disclosure, of a thin-film solar cell comprising a support 42 on which solar cells 43 are applied, which in turn are formed in a monolithic connection of the support 42. Located at the first and the last thin-film solar cell 43 of the series-connected solar cells are current collecting paths 44, 45 which contact current paths 46 and 47 through holes 50 through the support 42, which are filled with conducting material, such as cold filling 51, by cold spraying. The current paths 46, 47 are brought together at a junction box 49 provided on the side facing away from the sun and the cell layers for connection of external electrical conductors.

According to an embodiment of the present disclosure shown in FIG. 7B, no current paths are provided here since one of the junction boxes 49 is attached on the side facing away from the cell layers directly to each of the contact fillings 51.

It is also possible, according to the present disclosure, to eliminate the current paths if one junction box is positioned directly on the current collecting paths.

The equal-length current paths 6 and 7, as shown, for example, in FIG. 1, usually run approximately centrally to the entire thin-film solar module directly over the individual thin-film solar cells. This equal-length feature results, for example, in accordance with the present disclosure, in junction box 20 being horizontally centered, as shown, for example, in FIGS. 4 and 5.

In accordance with the present disclosure, an encapsulation layer, for example, made of plastic, can be applied over the contacts, in particular, the current collecting paths and current paths, as protection from the weather, either transparent or non-transparent depending on the design.

Although the present disclosure has been described and illustrated in detail, it is to be clearly understood that this is done by way of illustration and example only and is not to be taken by way of limitation. The scope of the present disclosure is to be limited only by the terms of the appended claims.

We claim:

1. A method for forming at least one electrically conducting contact area on a thin-film solar module, the method steps comprising:
providing a plurality of film solar cells including cell material layers;
applying the thin-film solar cells to a support material; and
forming the at least one electrically conducting contact area on the thin-film solar module by using a cold gas spraying process.

2. The method according to claim 1, wherein the at least one contact area is configured as at least one current collecting path on a first and a last solar cell of interconnected solar cells of the thin-film solar module and the at least one current collecting path is formed or fixed on the thin-film solar module by the cold gas spraying process.

3. The method according to claim 2, wherein the at least one contact area is configured as at least one current path which connects the at least one current collecting path in a conducting manner to a connection device for external electrical conductors and that the at least one current path is formed or fixed on the thin-film solar module by the cold gas spraying process.

4. The method according to claim 3, wherein one of both of the at least one current collecting path and the current path include only material applied to the thin-film solar module by the cold gas spraying process.

5. The method according to claim 1, wherein a conducting strip material is applied to the thin-film solar module by the cold gas spraying process.

6. The method according to claim 1, wherein a metal is applied to the thin-film solar module by the cold gas spraying process, which metal, at least when impinging upon the thin-film solar module, has a temperature below its melting point under process conditions prevailing at the location of the impingement.

7. The method according to claim 1, wherein a metal is sprayed onto the thin-film solar module by the cold gas spraying process in such a manner that when the metal is impinging upon the thin-film solar module, it has a maximum temperature of less than 300° C.

8. The method according to claim 7, wherein after application to the thin-film solar module, the sprayed-on metal is heated in certain areas to a temperature of more than 50 of the melting point of the sprayed-on metal.

9. The method according to claim 7, wherein the sprayed on metal includes one or more of aluminium, copper, nickel, and tin applied to the thin-film solar module by the cold gas spraying process.

10. The method according to claim 7, wherein zinc is the metal applied to the solar module by the cold gas spraying process.

11. The method according to claim 7, wherein the sprayed-on metal includes a mixture of different pure metals.

12. The method according to claim 7, wherein the metal is sprayed on with a Laval nozzle.

13. The method according to claim 1, wherein the cold gas spraying process is accomplished using a metal powder, which metal powder has a grain size of more than 35 μm.

14. The method according to claim 4, wherein a cross-sectional area of the at least one current collecting path or the at least one current path applied by the cold gas process is not rectangular.

15. The method according to claim 14, wherein the cross section of the at least one current collecting path or the at least one current path is less than 2 mm².

16. The method according to claim 14, wherein the cross section of the at least one current collecting path or the at least one current path is less than 0.7 mm².

17. The method according to claim 2, wherein the at least one current collecting path of the thin-film solar module is applied in the cold gas spraying process and that the at least one current path includes metal strips that are applied to the thin-film solar module.

18. The method according to claim 2, wherein the at least one of the current path is formed in one or more free edge zones of the thin-film solar module.

19. The method according to claim 2, wherein some sections, of the at least one current collecting paths rest on free edge zone and in some sections one or more of the cell material layers of the thin-film solar cell material overlap in an edge region.

20. The method according to claim 2, wherein the at least one current path is separated from the thin-film solar cells by an insulation structure which is applied to the cell material layers.

21. The method according to claim 1, wherein a back glass of the thin-film solar module has at least one hole which is penetrated by the electrically conducting contact area which connects in a conducting manner a side of a substrate provided with the thin-film solar cells to a side of the back glass facing away from the cell material layers.

22. The method according to claim 21, wherein a contact point is produced in a hole of the thin-film solar module by the cold gas spraying process.

23. The method according to claim 19, wherein one or both of the at least one of the current collecting paths and the at least one of the current paths is not formed in the free edge region of the support material but further centrally on the support material.

24. The method according to claim 21, wherein the thin-film solar module is formed as a glass-glass thin-film solar module, the at least one current collecting path being sprayed onto a substrate in an overlapping manner to a free edge zone and that the at least one current path is sprayed onto the back glass of the glass-glass thin-film solar module before assembly of the module.

25. The method according to claim 24, wherein the substrate has at least one hole which is penetrated by an electrically conducting contact filling which connects, in a conducting manner, the side of the substrate provided with the thin-film solar cells to the side of the substrate facing away from the thin-film solar cells.

26. A thin-film solar module comprising:
a support material;
a plurality of cell material layers applied to the support material;
at least one electrically conducting contact area formed on the thin-film solar module by a cold gas spraying process.

27. A thin-film solar module fabricated according to the method of claim 1.

28. The method of claim 1, wherein a metal is sprayed into the thin-film solar module by the cold gas spraying process in such a manner that, when the metal is impinging upon the thin-film solar module, it has a maximum temperature of less than 150° C.

29. The method according to claim 7, wherein after application to the thin-film solar module, the sprayed-on metal is heated in certain areas to a temperature of more than ⅔ of the melting point of the sprayed-on metal.

30. The method according to claim 14, wherein the cross section of the at least one current collection path or the at least one current path is less than 1 mm².

31. The method according to claim 14, wherein the cross section of the at least one current collection path or the at least one current path is less than 3 mm².

32. The thin-film solar module of claim 26, wherein the support material is one of a substrate and a superstrate.
